(19) United States
(12) Patent Application Publication
(10) Pub. No.: US 2013/0201634 A1
(43) Pub. Date: Aug. 8, 2013

(54) SINGLE-SCAN LINE-SCAN CRYSTALLIZATION USING SUPERIMPOSED SCANNING ELEMENTS

(71) Applicants: James S. Im, New York, NY (US); Paul C. Van Der Wilt, New York, NY (US)

(72) Inventors: James S. Im, New York, NY (US); Paul C. Van Der Wilt, New York, NY (US)

(73) Assignee: COLUMBIA UNIVERSITY, New York, NY (US)

(21) Appl. No.: 13/701,663

(22) PCT Filed: Dec. 30, 2010
(86) PCT No.: PCT/US10/62513

§ 371 Date: Mar. 11, 2013

Related U.S. Application Data
(60) Provisional application No. 61/351,065, filed on Jun. 3, 2010.
(60) Provisional application No. 61/354,299, filed on Jun. 14, 2010.

(51) Int. Cl. C30B 28/08; B23K 26/067; B23K 26/00

(52) U.S. Cl. CPC C30B 28/08; B23K 26/0081; B23K 26/067
USPC 361/748; 219/121.66; 219/121.77; 219/121.82; 219/121.65; 174/250

(57) ABSTRACT

The disclosure relates to methods and systems for single-scan line-scan crystallization using superimposed scanning elements. In one aspect, the method includes generating a plurality of laser beam pulses from a pulsed laser source, wherein each laser beam pulse has a fluence selected to melt the thin film and, upon cooling, induce crystallization in the thin film; directing a first laser beam pulse onto a thin film using a first beam path; advancing the thin film at a constant first scan velocity in a first direction; and deflecting a second laser beam pulse from the first beam path to a second beam path using an optical scanning element such that the deflection results in the film experiencing a second scan velocity of the laser beam pulses relative to the thin film, wherein the second scan velocity is less than the first scan velocity.

### CROSS REFERENCE TO RELATED APPLICATIONS

This application claims priority to U.S. Provisional Application No. 61/351,065 filed on Jun. 3, 2010 and U.S. Provisional Application No. 61/354,299 filed on Jun. 14, 2010.

All patents, patent applications, patent publications and publications cited herein are explicitly incorporated by reference herein in their entirety. In the event of a conflict between the teachings of the application and the teachings of the incorporated document, the teachings of the application shall control.

### BACKGROUND

Prior commercialized thin-film laser crystallization methods require multiple pulses per unit area of film to reach full crystallization. Examples of such methods include line-beam excimer laser annealing (ELA) and sequential lateral solidification (SLS). In order to enhance throughput, such processes are preferably performed in a way that each region in a film is scanned only once (i.e., a single-scan process). In practice, this typically means that samples are loaded on stages and scanned at a constant velocity while overlapping beam pulses impinge the surface of the film. Furthermore, lasers are typically operated at a constant repetition rate in order to maximize power output and throughput. Thus, for these methods, the overlap between pulses is the same throughout the film. For example, in a typical ELA process beams may overlap about 95% throughout the film; in a typical 2-shot SLS process using 2-D projection optics the beams (as used herein, 2-shot SLS refers to the SLS scheme in which two pulses are required to reach full crystallization of the film, in other words, each unit area of the film is being irradiated by at most two laser pulses) may overlap about 50% throughout the film (see, e.g., U.S. Pat. No. 6,908,835, “Method and System for Providing a Single-Scan, Continuous Motion Sequential Lateral Solidification”); and in a typical line-scan SLS process the beams may overlap less than 50% throughout the film for 2-shot SLS (see, e.g., U.S. Pat. No. 7,029,996 “Methods for Producing Uniform Large-Grained and Gain Boundary Location Manipulated Polycrystalline Thin Film Semiconductors Using Sequential Lateral Solidification”) or more than 50% throughout the film for directional SLS (see, e.g. U.S. Pat. No. 6,322,625 “Crystallization Processing of Semiconductor Film Regions on a Substrate, and Devices Made Therewith.”)

As an example, a schematic of the 2-shot line scan SLS process is shown in FIG. 1a. FIG. 1a shows a series of pulses 100 over a film 105. As shown in FIG. 1a, the overlap between the pulses is less than 50%. Therefore, at a 4 μm step size, i.e., each pulse moves 4 μm in a direction 101, and 6 kHz pulse repetition rate, the stage is moving at 2.4 cm/s to fully crystallize the film. Thus, given a certain lateral growth length and a certain laser repetition rate, the scan velocity is critical in properly creating the desired microstructure: for obtaining directional material (as used herein, directional SLS refers to the SLS scheme in which a collection of laterally grown grains is repeatedly epitaxially extended by further laser pulses that partially overlap with the laterally grown grains), the scan velocity has to be such that more than 50% overlapping between pulses occurs, while for obtaining the 2-shot microstructure, the scan velocity has to be such that less than 50%, but more than 0% overlapping between pulses occurs.

Fully crystallized films such as these can be used for manufacturing of large-area electronics applications, such as flat panel displays and X-ray sensors, which are commonly matrix-type devices. An example is an active-matrix backplane for a liquid-crystal display (LCD) or an organic light-emitting diode (OLED) display, wherein the nodes in the matrix correspond to pixel thin-film transistors (TFTs) or pixel circuits. In the manufacturing process, the Si in between the pixel TFTs or circuits is removed to allow for transparency. Thus, large regions in the crystallized film are not used.

In contrast to the methods discussed above, another type of crystallization scheme, selective area crystallization (SAC), uses sample alignment techniques (for example, using optical detection to locate fiducials or certain crystallization features) to enable selective crystallization of only those areas of a film where later devices or circuits are produced in a matrix-type large-area electronic device. Thus, beam pulses are directed to crystallize areas in which one or a multitude of nodes (e.g., a single column) in the matrix are later fabricated. Thus, by selectively crystallizing only the pixel TFTs or circuits and by skipping the areas in between, fewer pulses are needed to crystallize a sample, potentially resulting in higher throughput.

A single-scan SAC process with a constant laser repetition rate can be readily implemented for single pulse processes such as complete-melt crystallization or partial-melt crystallization. For example, the stage scanning velocity may be increased to skip areas between pulses. In other words, the distance traveled between two pulses can exceed the width of the beam (see e.g., U.S. Patent Application Publication No. 2007/001,0104, “Processes and systems for laser crystallization processing of film regions on a substrate utilizing a line-type beam, and structures of such film regions”).

For multiple pulse processes such as the prior commercialized processes ELA and SLS, SAC is less straightforward to establish in a single scan. In effect, a non-periodic placement of pulses at the film surface is required so that some pulses overlap while, periodically, some pulses are not overlapping (or are overlapping to a smaller degree) so that an area that need not be processed is not (or not fully) crystallized. Recently, techniques to effectively implement this technique using a system having multiple laser sources/tubes and by triggering the tubes with a slight delay have been developed. The delay corresponds to a short stage travel distance that allows for large overlapping within each sequence of pulses and small or no overlapping between each subsequent pulse sequence. Such a non-periodic pulse process can be used for a single-scan process using lasers operated at a constant repetition rate provided that (1) the number of pulses needed to reach full crystallization does not exceed the number of tubes, and (2) the area that is processed by each sequence of pulses is large enough to fully crystallize at least an area large enough to hold a single pixel TFT or circuit. An example is a 2-D projection 2-shot SLS process (see, e.g., U.S. application Ser. No. 12/776,756, “Systems and Methods for Non-Periodic Pulse Sequential Lateral Solidification”). In that example, two laser sources can be fired in short sequence to have largely overlapping rectangular pulses, wherein the width of the 2-shot crystallized region is wide enough to hold an entire pixel TFT or circuit and an appropriate margin to account for alignment inaccuracy (for example 10 s to 100 or 100 s of μms).

The desired non-periodic placement of pulses also can be performed using a laser operating in a burst mode, i.e., operating at a non-periodic firing rate, or with a beam blocking apparatus, to periodically block the beam at certain time intervals. However, such an implementation of SAC does not result in a throughput increase, but rather only in reduced use of laser pulses. Alternatively, the pulses may be redirected to another area on the sample or another sample. FIG. 1b depicts a burst mode or beam blocking 2-shot line-scan SLS method. In FIG. 1b, when the laser is on for irradiation of a first region 110 the laser irradiates the film 105 with four pulses. Then the laser is turned off or blocked for irradiation of a second region 115, resulting in no irradiation of the film 105. The laser is turned back on for irradiation of a third region 120, resulting in four pulses irradiating the film. Finally, for irradiation of a fourth region 125, the laser is turned off. The depicted scan proceeds at a velocity of 2.4 cm/s.

Some current commercialized pulsed-laser-based low-temperature polycrystalline Si processes do not readily meet both the requirements of a single-scan SAC process using multiple lasers operated at a constant repetition rate. For example, line-beam ELA commonly needs at least 10 or 15 or even 20 pulses per unit area and in some instances even 40 pulses to reach a satisfactory degree of material uniformity. While the non-periodic pulse technique may still benefit ELA (in reducing the number of scans as described in PCT/US10/55106, “Systems and Methods for Non-Periodic Pulse Partial Melt Film Processing”), it becomes impractical to build laser tools having 10 or more laser sources, e.g., because of more complicated and frequent maintenance of the crystallization tool, as well as more complicated optical setups required to combine the pulses. Hence, multiple scans are needed to reach full crystallization. In one scan each region of interest is processed by one or a small number of pulses. Upon each next scan the same region is processed again with further pulses until full crystallization is reached.

In contrast to ELA, line-scan SLS does meet the requirement of a small number of pulses needed to reach full crystallization; however, the area that is crystallized by such a small number of pulses is not sufficiently wide to fully crystallize a region for a pixel TFT or circuit. For example, the line beam may be 6 μm wide resulting in a lateral growth length of 3 μm, i.e., one half of the beam width. Upon a second irradiation with approximately 33% overlap (step size of 4 μm, beam width of 6 μm), a column of elongated grains is formed each having a length of about 4 μm. While this may be sufficient to hold the channel of a single short-channel TFT, it will be insufficient to hold longer channel TFTs, the source drain areas of the TFTs, a multitude of TFTs designed in a particular layout (that could include certain TFTs to have a channel direction perpendicular to the elongation direction of the grains), or other electronic elements such as storage capacitors. In addition, alignment techniques may not offer sufficient accuracy and margins may be required of at least a few or five or maybe ten or tens of μm. In all, this may add up to a requirement of as many as 10 pulses or even 20 or more to entirely process a region sufficiently large to hold a pixel TFT or circuit. Thus, the situation is equivalent to that of conventional line-beam ELA: a single-scan, constant-repetition-rate SAC process is not readily performed with known methods.

Thus, previously proposed SAC schemes involving line-beam ELA or line-scan SLS would typically need to involve multiple scanning (e.g., for line-beam ELA, PCT/US 10/55106, “Systems and Methods for Non-Periodic Pulse Partial Melt Film Processing” and for line-scan SLS, U.S. application Ser. No. 12/776,756, “Systems and Methods for Non-Periodic Pulse Sequential Lateral Solidification”). SAC schemes also exist wherein the laser source is not operated at a constant repetition rate, however, as discussed above, such a mode of operation (having lower laser power) does not lead to any increase in throughput, but merely in an increase of laser tube lifetime.

### SUMMARY

In one aspect, the present disclosure relates to a method for processing a thin film. The method includes generating a plurality of laser beam pulses from a pulsed laser source, wherein each laser beam pulse has a fluence selected to melt the thin film and, upon cooling, induce crystallization in the thin film; directing a first laser beam pulse onto a thin film using a first beam path; advancing the thin film at a constant first scan velocity in a first direction; and deflecting a second laser beam pulse from the first beam path to a second beam path using an optical scanning element such that the deflection results in the film experiencing a second scan velocity of the laser beam pulses relative to the thin film, wherein the second scan velocity is less than the first scan velocity.

In some embodiments, each laser beam pulse has a fluence selected to completely melt the thin film. In some embodiments, the method of crystallization includes a sequential lateral solidification (SLS) process. In some embodiments, each laser beam pulse has a fluence selected to partially melt the thin film. In some embodiments, the crystallization method comprises a line beam excimer laser annealing (ELA) process. In some embodiments, the optical scanning element is selected from the group consisting of a tilting mirror, a rotating mirror, a linearly movable optical element and a polygonal scanner. In some embodiments, the optical scanning element includes a polygonal scanner and the second pulse is directed to a same facet as the first pulse. In some embodiments, the optical scanning element includes a polygonal scanner and the second pulse is directed to a different facet as the first pulse. In some embodiments, the crystallization is complete in a single scan. In some embodiments, the method includes directing a third beam pulse onto the thin film using the first beam path.

Another aspect of the present disclosure relates to a method for processing a thin film, including the steps of: defining a plurality of regions comprising a first region and a second region; generating a plurality of laser beam pulses from a pulsed laser source, wherein each laser beam pulse has a fluence selected to melt the thin film and, upon cooling, induce crystallization in the thin film; advancing the thin film at a constant first scan velocity in a first direction resulting in a first scan direction; and deflecting at least two of the laser beam pulses using an optical scanning element such that the beam pulses scan the first region in the film at a second scan velocity until the first region is entirely processed, wherein the second scan velocity is less than the first scan velocity.

In some embodiments, each laser beam pulse has a fluence selected to completely melt the thin film. In some embodiments, the method of crystallization includes a sequential lateral solidification (SLS) process. In some embodiments, each laser beam pulse has a fluence selected to partially melt the thin film. In some embodiments, the crystallization method includes a line beam excimer laser annealing (ELA) process. In some embodiments, the optical scanning is selected from the group consisting of a tilting mirror, a rotating mirror, a linearly movable optical element and a polygonal scanner. In some embodiments, the optical scanning element includes a polygonal scanner and a second laser pulse is directed to a same facet as a first laser pulse. In some embodiments, the optical scanning element includes a polygonal scanner and a second laser pulse is directed to a different facet as a first laser pulse. In some embodiments, the crystallization is complete in a single scan. In some embodiments, the method includes after the first region is scanned at the second scan velocity, irradiating the second region at the first scan velocity.

Another aspect of the present disclosure relates to a thin film processed according to the methods above. Another aspect of the present disclosure relates to a device including a thin film processed according to the methods above, wherein the device includes a plurality of electronic circuits placed within the plurality of crystallized regions of the thin film. In some embodiments, the device can be a display device.

One aspect of the present disclosure relates to a system for crystallization of a thin film, the system including a pulsed laser source generating a plurality of laser beam pulses, wherein each laser beam pulse has a fluence selected to melt the thin film and, upon cooling, induce crystallization in the thin film; optics for directing the laser beam onto the thin film using a first beam path; a constant velocity scanning element for securing the thin film and advancing the thin film at a constant first scan velocity in a first direction resulting in a first scan direction; and an optical scanning element for deflecting the laser beam from the first beam path to a second beam path such that the deflection results in the film experiencing a second scan velocity of the laser beam pulses relative to the thin film, wherein the second scan velocity is less than the first scan velocity.

In some embodiments, the optical scanning is selected from the group consisting of a tilting mirror, a rotating mirror, a linearly movable optical element and a polygonal scanner. In some embodiments, the optical scanning element includes a polygonal scanner and a second laser pulse is directed to a same facet as a first laser pulse. In some embodiments, the optical scanning element includes a polygonal scanner and a second laser pulse is directed to a different facet as a first laser pulse. In some embodiments, the crystallization is complete in a single scan.

### BRIEF DESCRIPTION OF THE DRAWINGS

The following description will be more readily understood with references to the following drawings in which:

FIG. 1a depicts a conventional 2-shot line scan SLS process.

FIG. 1b depicts a burst mode or beam blocking 2-shot line-scan SLS process.

FIG. 2 depicts a scan of a film by moving a mirror linearly in the y direction during a scan, where the film moves at a constant velocity in the (−y) direction, according to embodiments of the present disclosure.

FIG. 3 depicts a superimposed scan of film using a rotating mirror, according to embodiments of present disclosure.

FIG. 4 schematically illustrates an embodiment of a system that can be used for a superimposed scan in order to crystallize a thin film, according to embodiments of the present disclosure.

FIG. 5 depicts a superimposed 2-shot line scan SLS process, according to embodiments of the present disclosure.

FIG. 6 depicts a superimposed 2-shot line scan SLS process, according to embodiments of the present disclosure.

FIG. 7 depicts waveforms of beam displacement induced by the variable-rate scanning element vs. time, according to embodiments of the present disclosure.

FIG. 8 depicts illustrates an embodiment of a system that can be used for a superimposed scan in order to crystallize a thin film, according to embodiments of the present disclosure.

FIG. 9 depicts a superimposed scan of a film, according to embodiments of the present disclosure.

### DESCRIPTION

Accordingly, greater crystallization throughput can be achieved by (1) using a minimum number of scans (preferably a single scan) and by (2) using a selective area crystallization scheme, while (3) running the laser(s) at a constant repetition rate. Increasing throughput is presently considered a critical development for implementing pulsed-laser-based low-temperature polycrystalline Si (LTPS) technology for large panel manufacturing (for example, gen-8 motherglass, i.e., 2.20×2.50 m²). Such technology could benefit active matrix light emitting diode (AMOLED) TV manufacturing as well as ultra-high definition LCD (UDLCD) manufacturing. High performance backplanes are particularly desired for 3D-TV application where refreshment rates of, for example, 240 Hz are required.

Here, a technique is presented that can allow single-scan selective-area crystallization with constant laser repetition rate for line-beam ELA or line-scan SLS. As described below, a non-periodic placement of pulses can be created using a periodic pulse sequence coupled with the ability to redirect the laser pulses on the region of interest. Thus, a single scan with variable scan rate is described wherein a low effective scan velocity is used in the regions of interest and a high effective scan velocity is used in the regions in between. The term effective scanning velocity, as used herein, refers to the speed and direction of the irradiations experienced at the surface of the film.

Thus, the present system uses two superimposed scanning elements to effectively create a single scan with variable scan velocity. While one scanning element scans the beam at a constant velocity that may be higher than the scanning velocity in a conventional set up (for example, double or triple), a second scanning element may alternate between scanning in a parallel and an anti-parallel direction (i.e., the opposite direction), to the first element. The sample is then crystallized with an effective scan velocity that is the result of superimposing the scan velocities of the two scanning elements: a low effective scanning velocity when scanning in anti-parallel mode and a high effective scanning velocity when scanning in parallel mode. Recognizing that the stage on which the sample lies is heavy and therefore difficult to accelerate or decelerate at sufficient rate, the constant velocity scan would be best carried out using the sample stages. Alternatively, the sample can be stationary and the beam can be scanned for example by scanning part or all of the beam delivery system or even the laser as well. The variable velocity scan then can be carried out using moving optical elements or beam deflecting elements. The beam deflecting elements can be, in one embodiment, for example, a rotating mirror (operated in a back and forth “seesawing” mode: e.g. galvanometer-based optical scanners available from Cambridge Technology, Lexington, Mass.). In another embodiment, the variable velocity scan can entail placing certain optical elements on a translation stage and scanning the optical elements back and forth, or through the use of a rotating polygonal mirror. Such techniques are generally known to people skilled in the art. Care must be taken that while scanning the beam, the beam properties at the sample level are unchanging (at least, during the low velocity scan). For example, if a focused line beam is used, the beam path between the focusing element and the sample preferably remains constant or varies not more than the focus depth of the beam. In rotational scanning (either galvanometer-based optical scanners or polygon scanners), a scan lens may be used (for example, lenses available from Bay Photonics LLC of Canton, Mass.) to compensate for variations in the beam path length if the angle of scanning becomes too large.

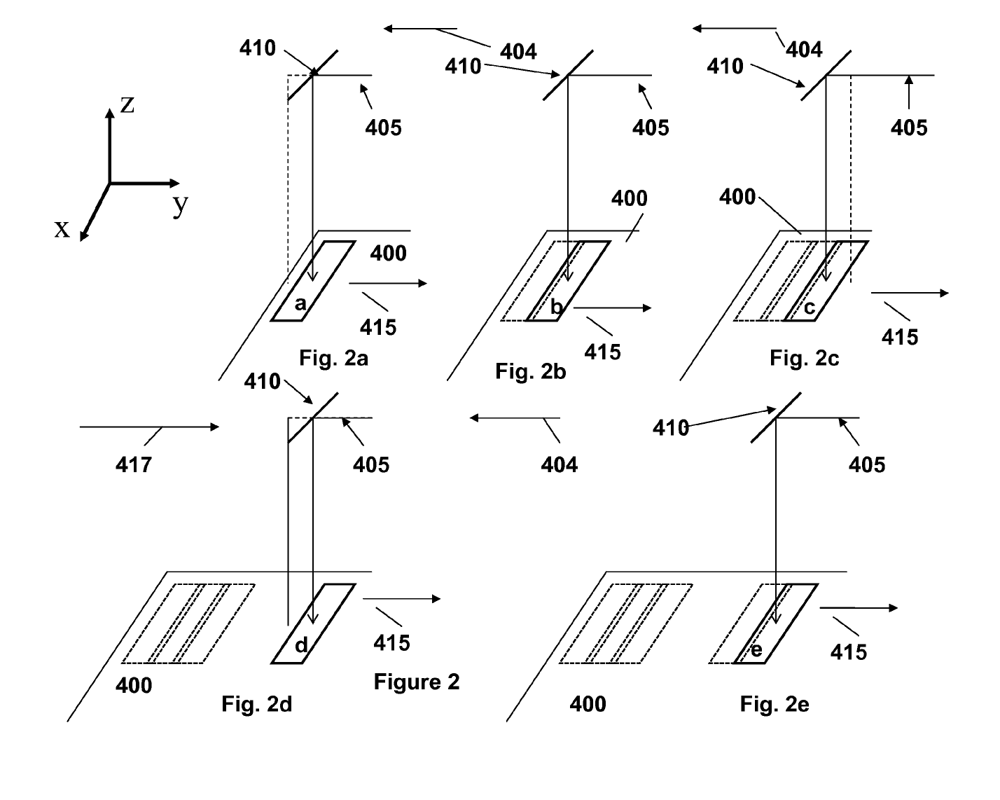

FIG. 2 depicts a scan of a film 400 by moving a mirror linearly in both the (+y) and (−y) directions during a scan, while the film moves at a constant velocity in the (−y) direction. The film moving in a constant velocity in the (−y) direction results in a scan in the (+y) direction 415, referred to as the long scan herein. In FIG. 2a, to start the short scan, i.e., the scan using the variable velocity scanning element, the mirror 410 is moved in the (+y) direction closer to the laser beam 405, resulting in the laser beam being redirected to and irradiating the film at location a. In FIG. 2, the mirror 410 serves as the variable scanning element and the moving film 105 serves as the constant velocity scanning element. Further, the scan created by the mirror 410 (and any variable rate scanning element disclosed herein) is referred to herein as the short scan and the scan by the film 105 is referred to herein as the long scan. The superimposed scanning discussed herein will be referred to in terms of scanning velocities, scanning elements, and short/long scans. From its starting position, the mirror is moved in the (−y) direction (arrow 404) to start the short scan, i.e., anti-parallel to the long scan direction of the constant velocity scanning film. In FIG. 2b, the mirror is returned to a center position, resulting in the laser beam being directed to and irradiating location b on the film. In FIG. 2c, the mirror 410 is moved away from the laser beam 405 (in the (−y) direction 404) resulting in the laser beam being directed to and irradiating location c on the film. Regions a, b, and c are all overlapping with the required overlap, e.g., 2 μm in a line-scan 2-shot SLS process. This completes the crystallization of a first area for later TFT pixel or circuit manufacturing and completes the short scan. In FIG. 2d, the film continues to move in the (−y) direction while the mirror has been moved back to its starting position in FIG. 2a, that is, the mirror has moved in the (+y) direction or parallel to the long scan (arrow 417). This starts a second short scan. The movement toward the laser beam 405 causes the laser beam being directed to and irradiating location d on the thin film, which is the first pulse in a second area for TFT pixel or circuits and which does not overlap with the first area. The process continues as previously; in FIG. 2e, the mirror is returned to its central position, resulting in the laser beam being directed to and irradiating location e on the film.

The mirror 410 is thus a variable rate scanning element that alternates between scanning the beam back and forth in the y direction. In most cases, the beam will not directly impinge on the film, but first will be further shaped by optical elements, for example a projection lens or other refractive or reflective optics. In principle, the variable rate scanning element may be placed anywhere in the optical beam path as long as it is placed beyond elements that divide and overlap the beam, such as, for example, lenslet arrays that are typically used to homogenize a beam. To limit the size of the variable rate scanning element, it may be desirable to place it further upstream (i.e., closer to the laser source) before one of the axes of the beam is expanded to form a line beam.

The optical elements define an optical path along which light propagates through the system. The optical path is commonly defined by an imaginary line that is referred to as the optical axis. For a system composed of simple lenses and mirrors, the optical axis passes through the center of curvature of each surface, and coincides with the axis of rotational symmetry. The dotted line throughout FIG. 2a-2e schematically shows the optical axis of such optical elements (dotted line), i.e., of the optical path. Typically, in beam delivery systems, the beam preferably travels over a beam path that is close to the optical axis so as to minimize optical distortions that may result from off-axis travel. The variable rate scanning element deflects the beam onto a beam path that deviates from the optical axis. As used herein, the beam path is the actual path that the beam travels along an optical path that is defined by optical elements and that can be described by an optical axis.

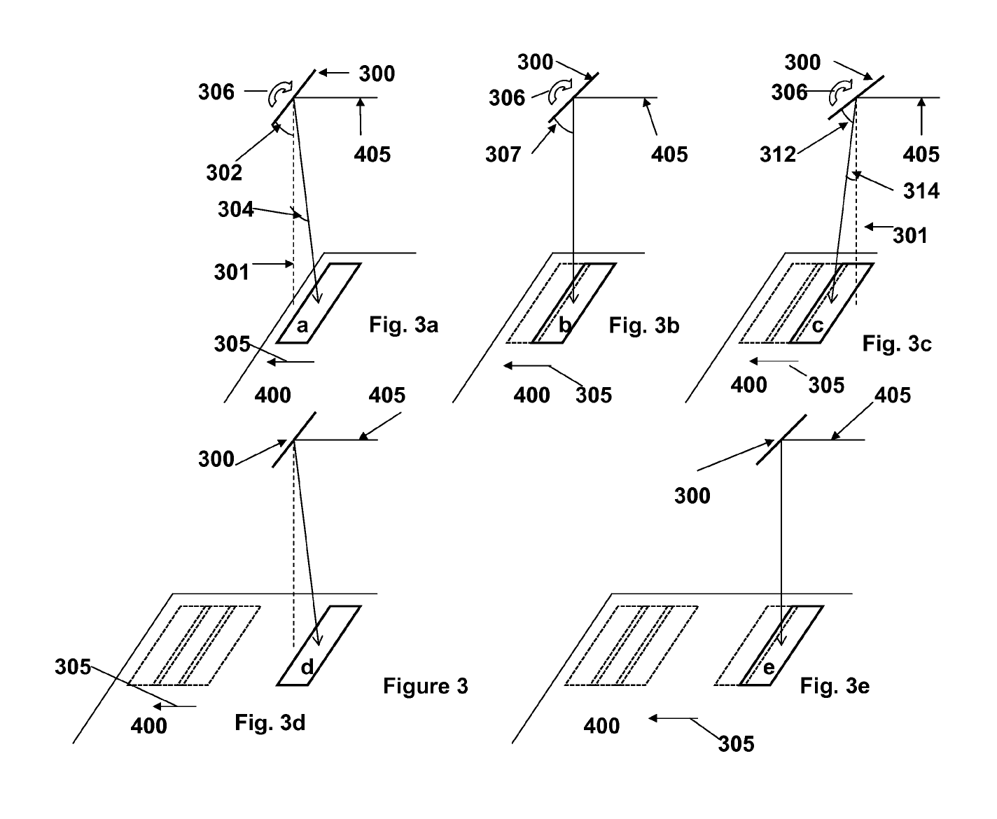

The variable rate scanning element is capable of rapidly altering scanning directions. This may be demanding for translational scanning elements, for instance when the velocity of shifting a large mass back and forth over a certain distance becomes too large. Alternatively, rotating or tilting scanning elements may be used. FIG. 3 depicts this concept. Rather than a mirror moving from and towards the beam, the mirror is now stationary, but rotating around an axis in the direction of arrow 306 to deflect the beam from the optical axis. In FIG. 3a, beam 405 is directed to mirror 300 that is positioned at an angle 302 to the optical axis 301 and therefore deflects beam at an angle 304 from the optical axis. This results in the beam being redirected to irradiate a location a of the film 400. FIG. 3b depicts a laser beam being directed to mirror 300 that is now positioned at angle 307 from the optical axis resulting in no deflection from the optical axis. Thus, the beam irradiates location b on the film 400. FIG. 3c depicts the beam 405 being directed to mirror 300 that is now positioned at an angle 312 from the optical axis 301 and therefore deflects beam at an angle 314 from the optical axis. This deflection results in the beam being redirected to irradiating location c of the film 400. FIG. 3d depicts regions a, b, and c are all overlapping with the required overlap, e.g., 2 μm in a line-scan 2-shot SLS process. This completes the crystallization of a first area for later TFT pixel or circuit manufacturing. In FIG. 3d, the film continues to move in the (−y) direction (arrow 305 and resulting in a scan of the film in the (+y) direction) while the mirror has been moved back to the first position in FIG. 3a at an angle 302. The deflection of the beam causes the laser beam being directed to and irradiating location d on the thin film, which is the first pulse in a second area for TFT pixel or circuits and which does not overlap with the first area. The process continues as previously; in FIG. 3e, the mirror is returned to the position in 3b at an angle 307, resulting in the laser beam being directed to and irradiating location e on the film.

The rotating mirror that is, for example, controlled by a galvanometer or some type of linear microactuator that is used to tilt the mirror, still requires reverse scanning before the next area can be crystallized. Such reverse scanning will proceed at the expense of process throughput since pulses emitted during that time will not be overlapping with either of the areas for pixel TFTs or circuits. Such pulses may be considered wasted pulses.

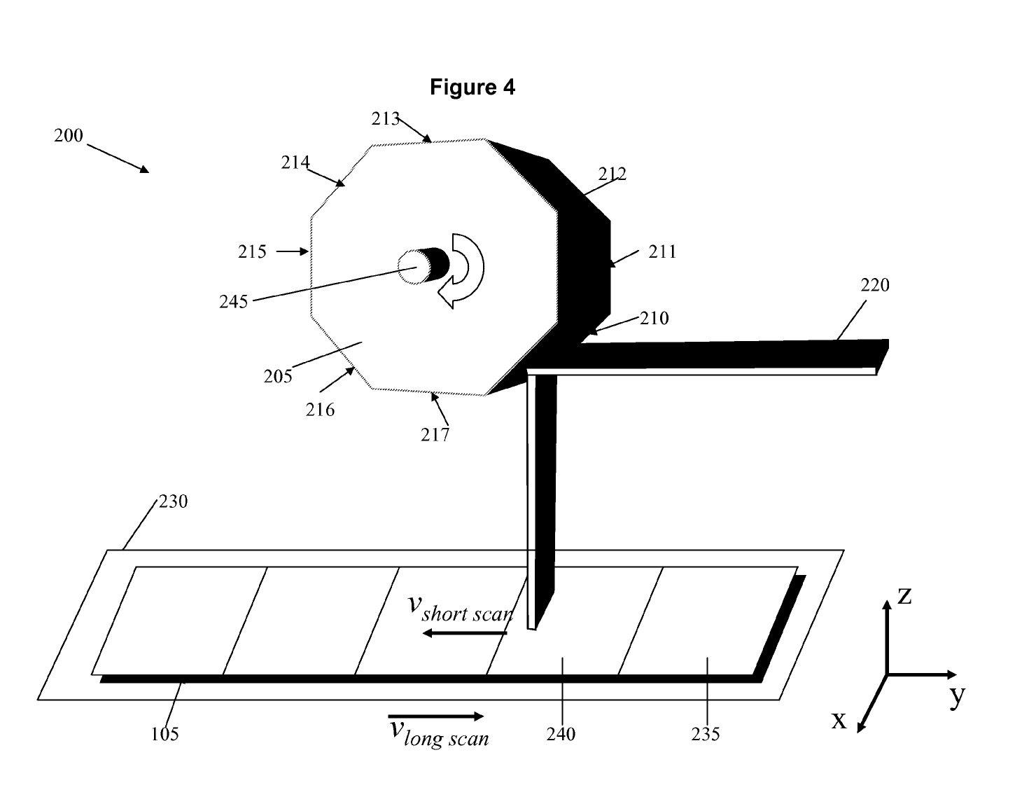

FIG. 4 schematically illustrates another embodiment of a system 200 that can be used for a superimposed scan in order to crystallize a thin film 105. The superimposed scanning system 200 includes a rotating disk 205 with a plurality of facets 210-217 (a polygonal scanner), each of which is at least partially reflective. A laser beam 220 is directed at the rotating disk 205, which is arranged such that the facets redirect the laser beam 220 so that it irradiates the film 105. As the disk 205 rotates, it causes the laser beam 220 to scan the surface of the film 205, thus crystallizing successive portions of the film 105. As the disk 205 continues to rotate, each new facet that reflects the laser beam effectively “resets” the position of the beam relative to the film in the direction of rotation, bringing the laser beam back to its starting point on the film in that direction. In other words, the reverse scan is instant and not at the expense of process throughput. At the same time, the film is translated in the (−y) direction at a constant velocity, (resulting in a scan in the (+y) direction at a constant velocity) so that as the disk continues to rotate, new facets reflect the laser beam onto subsequent areas in the film. In FIG. 4, the polygonal scanner 205 serves as the variable scanning element and the moving stage 230 serves as the constant velocity scanning element. Further, the scan created by the rotating disk 205 is referred to herein as the short scan and the scan by the stage 230 is referred to herein as the long scan.

Specifically, facets 210-217 are arranged so as to redirect a pulsed laser beam 220 so that laser beam 220 irradiates film 105 within defined region 240. Where the laser beam 220 irradiates region 240, it melts the film 105, which crystallizes upon cooling. Disk 205 rotates about axis 245. This rotation moves facets 210-217 relative to laser beam 220, so that they behave as a moving mirror for the laser beam 220, and guide the beam 220 in a line across the film 105. The movement of facets 210-217 move laser beam 220 relative to film 105 in the (−y) direction. The relative velocity V_{short scan} of the beam relative to the film 105 in the (−y) direction is determined by the speed of rotation of disk 205. At the same time, stage 230 moves film 105 in the (−y) direction corresponding to a scanning velocity v_{long scan} in the (+y) direction, i.e., in a direction anti-parallel to the short scan direction of rotating disk 205. Thus, the net beam velocity relative to a given point of the film would be the sum of v_{short scan} and v_{long scan}. Therefore, the stage can move at a high velocity, for example, 4.8 cm/s, while the short scan can be at a velocity of −2.4 cm/s, thereby resulting in an effective velocity of 2.4 cm/s. Furthermore, the irradiation pattern of the film surface is defined by the stage scanning speed and direction as well as the facet size and rotation rate of the disk, as well as the distance between the disk and the film.

A sequence of pulses is thus reflected by one facet before further rotation of the polygonal mirror. The rotation causes the next sequence of pulses to be reflected by the neighboring facet. This mode can thus be referred to as “short scan per facet” or just “scan-per-facet.” Between shifting entirely from reflection of one facet to that of the next facet, one or more pulses may be reflected of the corner region between the two facets. Those pulses will not be correctly imaged on the film surface and are considered as wasted pulses for not contributing to the crystallization of a certain area. Generally, it is preferable to minimize the number of wasted pulses by limiting the beam cross section in one dimension to be much smaller than the length of the facet.

While FIG. 4 shows faceted disk 205 with eight facets, this number of facets is meant to be illustrative only. In general, other ways of deflecting the beam in order to provide high velocity scanning are contemplated, for example, a single movable mirror. Or, for example, other numbers of facets can be used, according to the desired processing speed and size of the film.

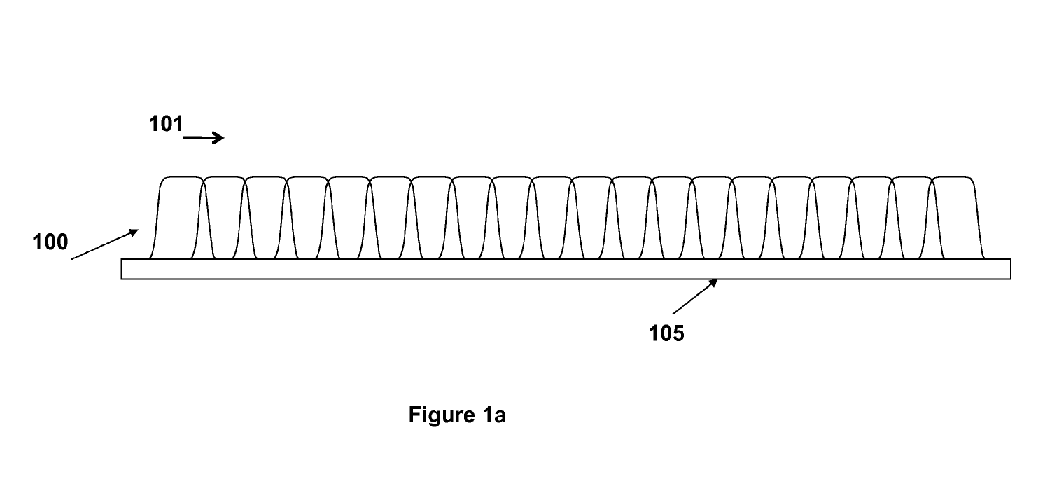

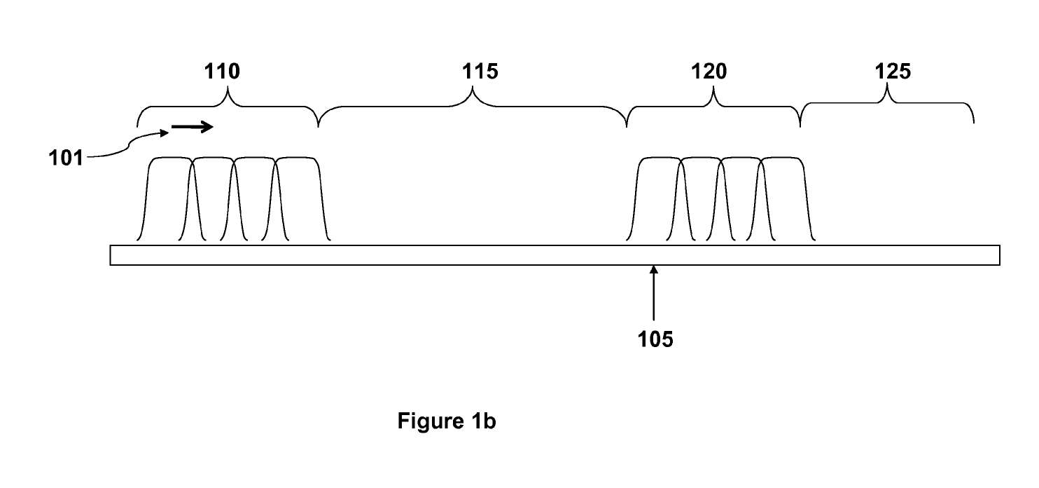

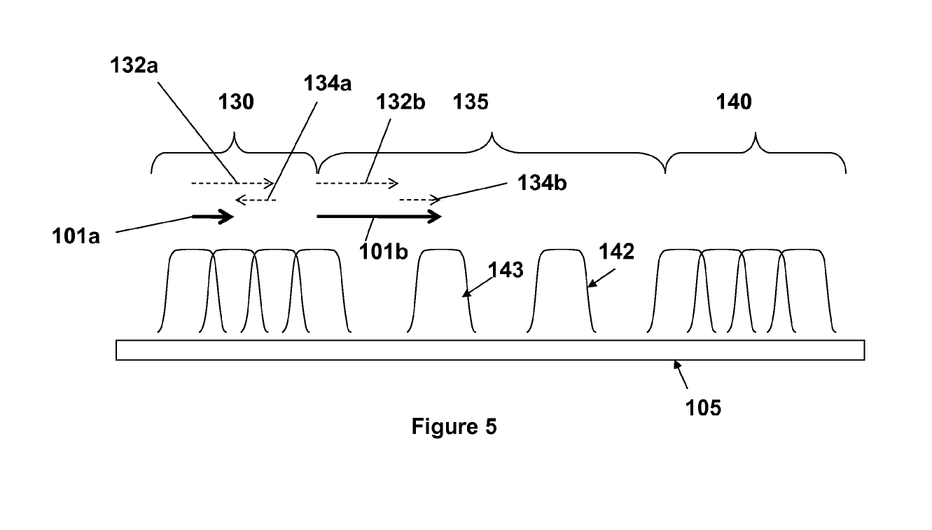

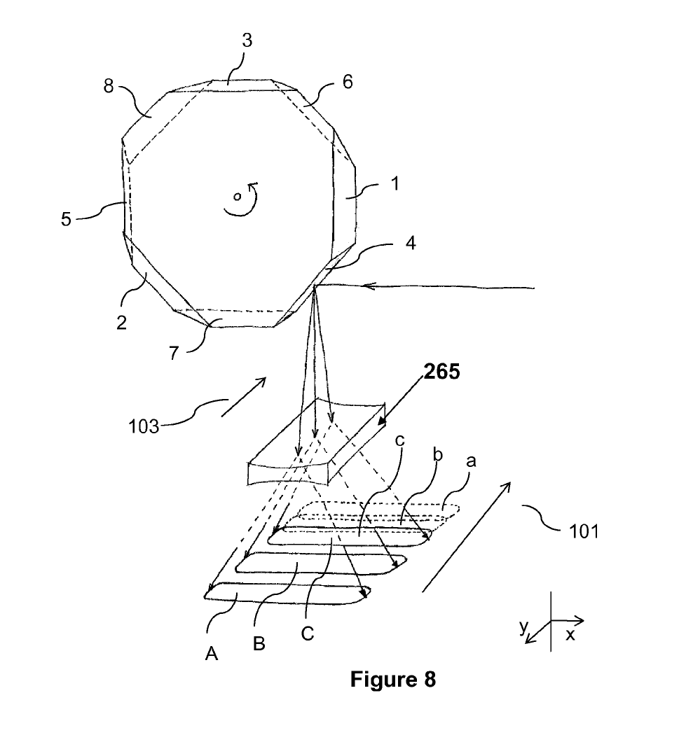

FIG. 5 depicts a superimposed 2-shot line scan SLS process across a film according to embodiments of the present disclosure. The y-axis is distance. The arrows 101a, 101b, 132a, 132b and 134a, 134b represent distances traveled across the film in the time interval between two laser pulses and therefore are correlated to the relative velocities of the scan. The scan involves advancing the film 105 to produce a constant velocity long scan in the (+y) direction 132a, b (the long scan velocity is a result of moving the film in the (−y) direction at this constant velocity). The velocity of the long scan 132, a, b can be, for example, 4.8 cm/s. At the same time, in a first region of the scan 130, a short scan is performed in an anti-parallel direction, i.e., the (−y) direction. The short scan velocity 134a in the anti-parallel direction can be, for example, −2.4 cm/s. Thus, an effective scan velocity 101a, which is the sum of the long scan velocity 132a and the short scan velocity 134a proceeds at a speeds of 2.4 cm/s in first region 130 (4.8 cm/s+−2.4 cm/s). Therefore, the first region 130 can experience a 2-shot SLS process similar to the process in FIG. 1a and FIG. 1b, but the stage moves at a higher rate of speed, i.e., 4.8 cm/s. A second region 135 depicts a parallel scan, where the short scan velocity 134b and the long scan velocity are in the same (+y) direction. Therefore, the effective scan is the sum of the 2.4 cm/s short scan velocity 134b and the 4.8 cm/s long scan velocity 132b, for a total effective scanning velocity of 7.2 cm/s. Depending on the short scanning element used, the parallel scan can result in one or more missed pulses (141, 142), that is, pulses that do not produce a two shot crystallization region. A third region 140 depicts another anti-parallel scan. Therefore, using the combination of parallel and anti-parallel scans, only selected portions of the film (first region 130 and third region 140) experience 2-shot SLS and the throughput of the scan can be increased. The anti-parallel scan results from the short scanning element redirecting the beam in the (−y) direction at a velocity proportional to the velocity of the scanning element (i.e., back and forth movement or rotation of the mirror). The parallel scan results from the “reset” of the short scan. Once the short scan is complete in the (−y) direction, the beam is directed to the beginning of the short scan, i.e., initial translation position (FIG. 2), the next facet in a scan-per-facet (FIG. 3), the first facet in a pulse-per-facet scan (FIG. 8) or the starting position of the galvanometer or microactuator controlled mirror. This movement of the beam to the starting position results in the parallel scan in the (+y) direction.

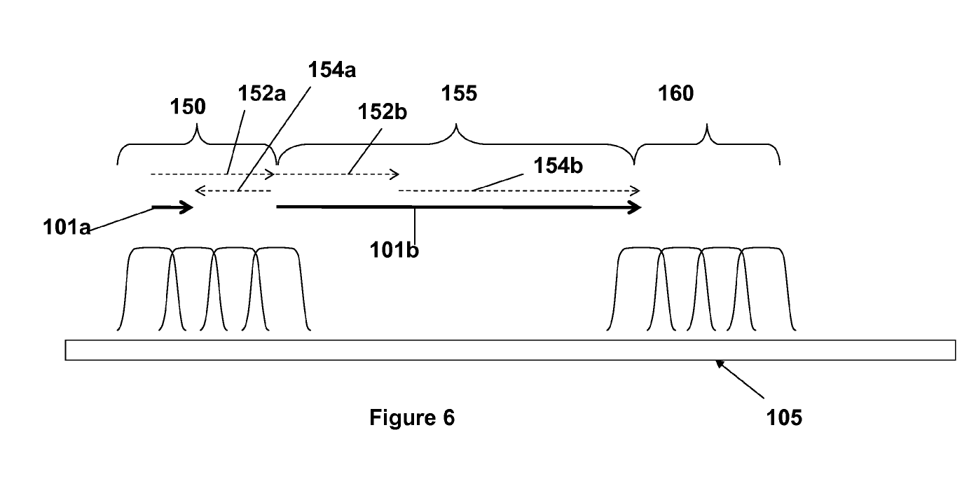

FIG. 6 depicts a superimposed 2-shot line scan SLS process according to embodiments of the present disclosure. FIG. 6 differs from FIG. 5 in that the variable rate beam scanner has a higher velocity in the parallel scan than in the anti-parallel scan, as indicated by the different distance between the two arrows 154a, 154b. During the anti-parallel scan, FIG. 6 shows a short scan velocity 154a of −4.8 cm/s (−8 μm displacement between 2 pulses) and a long scan velocity 152a of 7.2 cm/s (12 μm displacement between 2 pulses). Therefore, in the anti-parallel scanning regions 150, 160, the effective scan velocity is again 2.4 cm/s. On the other hand, in the parallel scanning region 155, the displacement between two pulses by the variable rate scanning element, right arrow 154b, is 24 μm. The average short scan velocity between those pulses is thus is 14.4 cm/s and the net beam velocity 101b is 21.6 cm/s. The displacement between these pulses by the variable rate scanner during the parallel scan need not be linear, so the velocity need not be constant. As shown in FIG. 6, the increased effective scanning velocity 101b in parallel scanning region 155 is large enough such that no pulses irradiate the film in the parallel scanning region 155 of FIG. 6, while in the parallel scanning region 140 of FIG. 5 has one or more irradiations. FIGS. 1a 1b, 5 and 6 are exemplary scans, showing a small number of pulses for illustrative purposes. The number of pulses and the pixel pitch can be larger in typical silicon processing applications.

Depending on the range of scanning velocities achievable by the variable velocity scanning element, the areas in between pixels may either be not at all or not fully crystallized. For example, the parallel scan may be sufficiently fast to allow the beam to reach the next region of interest between two consecutive pulses, as shown in FIG. 6. Or, it may be slower so that pulses still impinge the areas in between, but with no or insufficient overlap so that the area is not fully crystallized, as shown in FIG. 5.

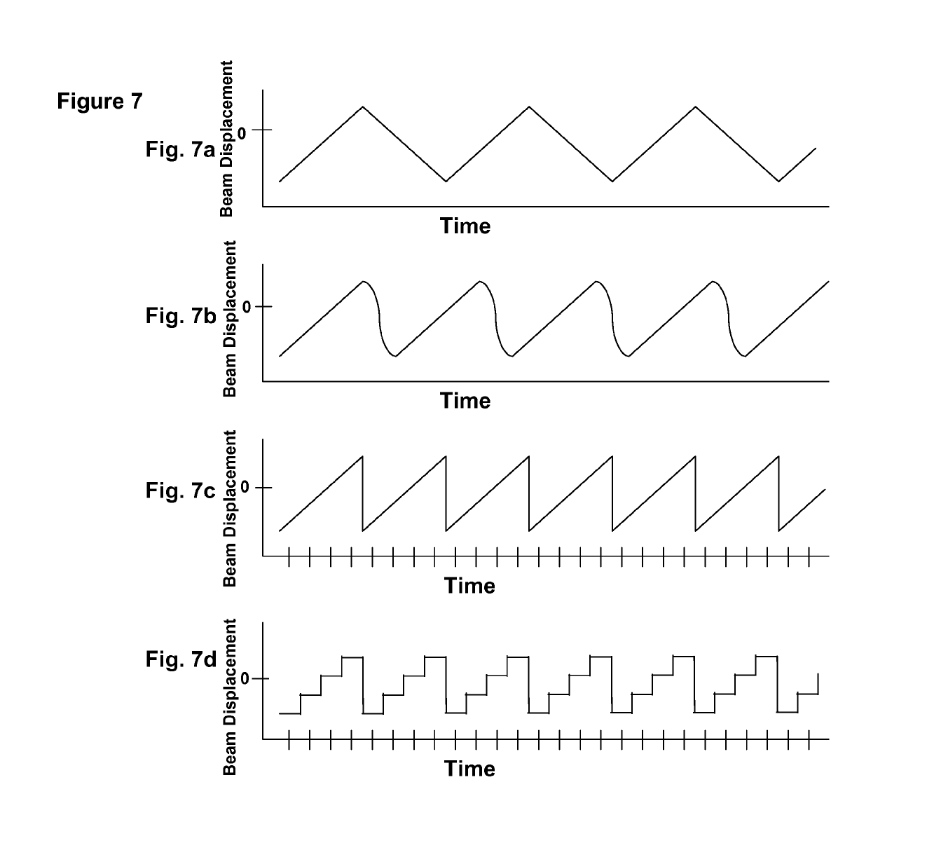

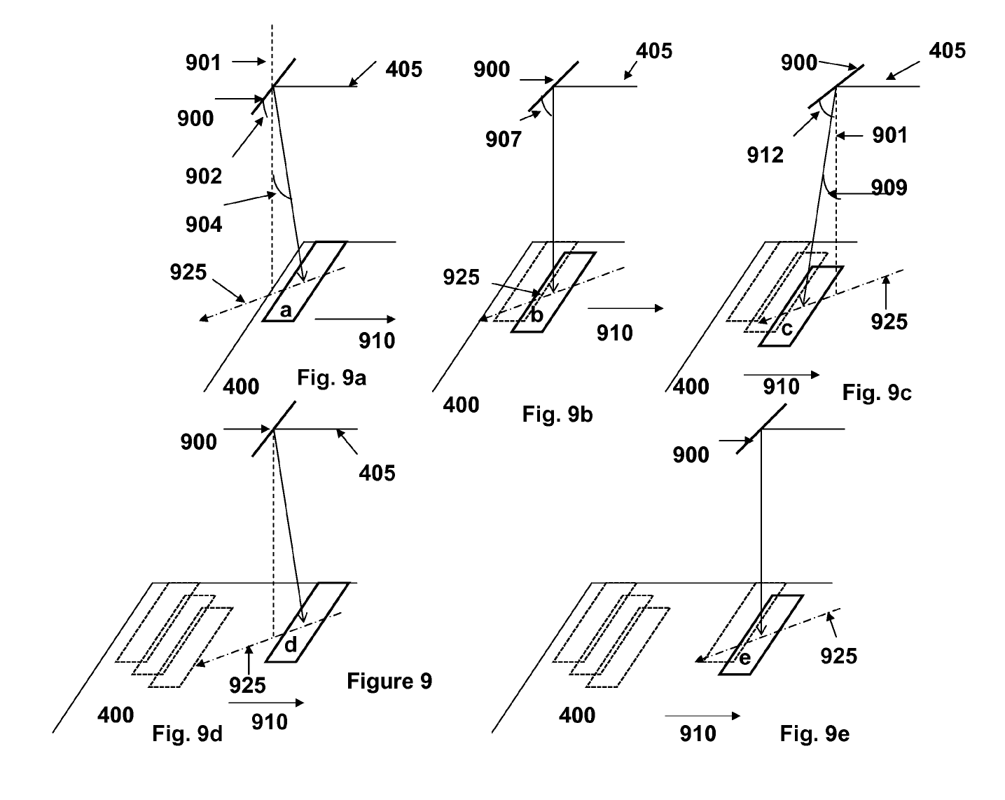

FIG. 7 shows the waveforms of the beam displacement around a certain central position (indicated by the origin on the vertical axis) and induced by the variable-rate scanning element (y-axis) vs. time (x-axis). The central position preferably coincides with the optical axis so as to minimize optical distortions. The variable rate beam scanner used in FIG. 3 and FIG. 9, having symmetry in the forward and the reverse scan velocity (used for the anti-parallel and the parallel scan, respectively), can have the triangular waveform of FIG. 7a, the result of which is for example as illustrated in FIG. 5. The variable rate beam scanner used in FIG. 3 and FIG. 9 can also have asymmetry in the forward and the reverse scan velocity and can be implemented with an asymmetric waveform like FIG. 7b, the result of which is for example as illustrated in FIG. 6. The variable rate beam scanner used in FIG. 4, having asymmetry in the forward and the reverse scan velocity can correspond to the saw-tooth waveform of FIG. 7c. The variable rate beam scanner used in FIG. 8 can correspond to the stair-like waveform like FIG. 7d. The vertical lines on the horizontal axis of FIG. 7c and FIG. 7d indicate the timing of laser pulses as corresponding to the example given in FIG. 6. It is evident from FIG. 7 that all these waveforms are adequate examples for a desirable scan rate in the anti-parallel scan so that the net beam scan velocity has the required value, in the above examples: 2.4 cm/s. The technique may further be combined with burst mode operation or beam blocking to avoid any pulses in the areas in between and/or to reduce the number of wasted pulses so as to increase laser tube life.

To maximize throughput, it is preferable to minimize the duration of the parallel scanning mode (i.e., the high velocity scan), so that most of the time the moving elements operate in anti-parallel scanning mode (i.e., the low velocity scan useful for crystallization). Galvanometer based scanners can be used in a way that the scan in one direction is slow and linear, while the scan in the reverse direction is fast and sinusoidal (shown in FIG. 7b and FIG. 3). A galvanometer based scanner has three components: a galvanometer, a mirror and a servo driver board that controls the system. The galvanometer has an actuator that manipulates the mirror and an integral position detector that provides mirror position information. The mirror is typically a mirror that can hold the required beam diameter over the required angular range of the scan. The servo circuitry drives the galvanometer and controls the position of the mirror. By controlled movement of the mirror, an incoming laser beam can be scanned in a controlled manner across a film.

While such an asymmetric scan velocity may be applicable to systems based on low-frequency lasers, for example, lasers used in line-beam ELA equipment from Japan Steel Works, Ltd. (Japan), it may not be feasible for systems based on high-frequency lasers, such as for instance used in thin-beam line-scan crystallization equipment from TCZ (San Diego, Calif.). For such high frequency lasers, the repetition rate of the variable rate scanning element can be higher, and asymmetric scan velocity such as in FIG. 7b is difficult to achieve using any optical element that scans in a back and forth motion. Any such motion requires acceleration and deceleration followed by motion in a reverse direction. The repetition rate of such back-and-forth motion depends on the number of pulses needed to fully crystallize a column of pixel TFTs or circuits and the laser repetition rate. To illustrate, 50 pulses are required to process a 200 μm wide column using a line-scan SLS process having a 4 μm step size. Then it follows that with, for example, a 6 kHz laser, the duration of the anti-parallel scan is 0.0083 seconds. Then, the repetition rate could be about 60 Hz for a symmetric scan velocity, or up to about 100 Hz if the reverse scan can be performed at higher velocity.

In an alternative embodiment, a rotating optical element is used with faceted mirrors (a polygonal mirror, for example, from Lincoln Laser Company, Phoenix, Ariz.) to create a saw-tooth like motion of the beam (FIG. 7c). The advantage of the rotating optical element is that it moves at a constant velocity, eliminating the need to accelerate and decelerate. A similar use of such an optical element was previously disclosed in a scheme to obtain very high scanning rates (e.g., around 1 m/s) in a continuous-wave laser scanning process with limited scan velocity of the stages (see WO 2007-067541, “System and Method for Processing a Film and Thin Films”). There, the rotating optical element was used to create a perpendicular scanning direction at a higher velocity. Very high scan velocities, i.e., 1 m/s, are needed for continuous-wave (CW) lasers to prevent damaging of the low-temperature-tolerant substrates used in large-area electronics. Thus, the variable rate scanning element was used to scan a CW laser at a much higher velocity than the allowable stage velocity by superimposing thereupon a very high scan rate in a perpendicular direction. Here, we are using similar elements to slow down the scan velocity in an anti-parallel scanning direction. Thus, each facet is irradiated by a short sequence of pulses that are overlapped on the sample surface to fully process one region (for example, the four pulses in FIG. 6). Further, the present method relates to a pulsed laser based process, not a continuous wave laser process, and a line-beam that has its long axis perpendicular to the stage movement, not parallel to stage movement. In one embodiment, with the polygonal mirror scanner, the scan linearly progresses in one direction and at the end of each facet is abruptly redirected to its beginning position on the next facet. It may be that one or more pulses are wasted on the edges between the facets. Burst mode operation may be used to prevent such extraneous pulses. Furthermore, to prevent drifting because of inaccuracies in the scan speed, encoders may be used so that the speed of the scanner can be regulated and synchronized to the rest of the system, for example, the pulse triggering of the laser.

In addition to doing short scans using a single facet (“scan-per-facet”), short scans also can be established using one facet per pulse wherein each facet directs each pulse to the desired location (“pulse-per-facet”), for example, by polishing the facets having a tilt angle with respect to the rotation axis of the scanner (so that the scan is in a direction perpendicular to the rotating facet in the previous paragraph). FIG. 8 depicts a rotating polygonal mirror 260 having eight facets for reflecting a laser beam 262. The rotating polygonal mirror 260 can be used in one embodiment of the present disclosure to create a short scan. The advantage is that higher rotation speeds may be used which results in more stable scanning Facets need not be consecutive, they can be every third facet, for example, a polygonal mirror having 10 facets can have a facet sequence as follows: 1-4-7-10-3-6-9-2-5-8-1. The facets also can be more than a single rotation apart. Generally, all the facets are positioned at different angles with respect to the axis of rotation of the polygonal mirror. For example, half of the facets can be tilted with a positive angle, while the other half of the facets could be tilted with a negative angle. The polygonal mirror depicted in FIG. 8 has 8 facets that are irradiated in the order 1-8. Each of the eight facets in FIG. 8 is tilted at a different angle with respect to the axis of rotation of the polygonal mirror. This causes a sweeping of the beam (which may have a rectangular cross section) in a direction perpendicular to the plane of rotation of the mirror (that is, parallel to the axis of the scanner that rotates the mirror): the (−y) direction 103. The beam then can be shaped into a line beam, for example, using simply a negative lens 265 as illustrated. While only a negative lens is shown in FIG. 2a, the processing system may include other, more sophisticated optics for focusing, directing and collimating the laser beam. If the sample is stationary, i.e., there is no long scan, this would result in irradiations of areas A, B, and C, which, depending on the scan velocity, could be spaced apart irradiations as illustrated or they can be overlapping. However, when the long scan velocity is non zero and the beam is scanned in the (+y) direction (for example, by moving the sample in a (−y) direction 101), the two scan velocities add up to the desired effective scan velocity 103. For example, to achieve a 4 μm step distance in a 2-shot line-scan SLS process as illustrated: areas a, b, and c.

The disclosed systems and methods have applications in selective area crystallization. In the selective-area crystallization of Si films for matrix-type electronics, regions corresponding to columns of pixel TFTs or circuits are crystallized. The width of the regions depends on the size of the electronics and the pitch of the columns (center to center spacing) depends on the desired display resolution. The pitch between crystallized regions is found to be ((number of pulses for the short scan)/(laser frequency))*(velocity of the stage); for example, in FIG. 1d: 4 pulses*((7.2 cm/s)/(6000 Hz))=48 μm. Assuming the laser frequency is a fixed parameter, then a larger pitch requires an increase in stage velocity, i.e., the long scan velocity. In order to maintain a certain preferred overlap between the laser pulses, an increase in the short scan velocity also is required, so that the effective scanning velocity remains the same. Following the same example, the stage velocity can be increased to 12 cm/s to give an 80 μm pitch. The variable scan-rate element then scans the beam at −9.6 cm/s in order to have the effective scan velocity in the areas of interest be the desired 2.4 cm/s. For a translational scanner, this could be achieved by increasing the amplitude of the back and forth scanning motion while keeping the frequency the same; hence, increasing the velocity. For rotational scanners, one way to increase the velocity of the variable scan rate element is to scan the beam over a larger angle. When a galvanometer-based scanner is used, the element can be scanned with higher velocity while keeping the same repetition rate and thus making a longer sweep (rotation over a larger angle). When a polygonal scanner is used to scan the beam (“scan-per-facet”), then a polygonal mirror with a smaller number of facets and rotated at a higher velocity may be used. For example, to scan at −9.6 cm/s instead of −4.8 cm/s, half the number of facets can be used with double the rotation velocity. When a polygonal scanner is used in a “pulse-per-facet” mode, a polygonal mirror may be used with facets that have a larger angle with respect to the axis of rotation. Alternative to scanning the beam over a larger angle (which may involve having to replace the faceted mirror), other optical solutions may be utilized to increase the velocity of the short scan, for example, changing the distance between optical elements downstream from the variable rate scanner.

On the other hand, if a wider crystallized region is required with an equal pitch, slower scan rates may be used. For example, if 6 pulses are needed with a pitch of 48 μm, the stage velocity should be 0.0048 cm*6000 Hz/6=4.8 cm/s. Like above for larger pitch, adjustments of the scan velocity of the short scan can be made accordingly.

The previous examples for creating larger pitch and wider crystallized region, respectively, assume no wasted pulses, which is not typically the case. If pulses are wasted between short scans, the formula is as follows: ((number of pulses for the short scan+number of wasted pulses between short scans)/(laser frequency))*(stage velocity). Thus, in FIG. 5: (4 pulses +2 pulses)*((4.8 cm/s)/(6000 Hz))=48 μm. If sample stages are used that have a limited (optimized) range of scan velocities, then in order to reduce the width of the crystallized region or increase the pitch between crystallized regions, it may be necessary to increase the number of wasted pulses (either by having pulses in between crystallized regions (FIG. 5) or having wider than necessary crystallized regions) or reducing the laser repetition rate.

When a single facet is used for performing short scans (“scan-per-facet”), the angle over which the beam is redirected with a polygonal scanner may be too large to allow for small pitched radiations (e.g., 4 μm steps in a 2-shot line-scan SLS process or 2 μm steps in a directional line-scan SLS process). For example, a 12-faceted polygonal mirror sweeps the beam over a 30 degree angle. The high angular velocity may result in a short scan velocity that is many times too high to allow for proper overlapping of the pulses. Instead, two scanners may be used scanning against each other to reduce the angle, see, e.g., U.S. Pat. No. 5,198,919, “Narrow field or view scanner.”

It should be noted that the effective scan velocity in the anti-parallel scanning need not be positive or in the same direction as the constant scan. For example, the effective scan direction may be in an opposite, negative, direction, or the effective scan velocity may be zero or almost zero. A zero effective scan velocity could be useful for a line-beam ELA process having a beam width that is sufficient to cover the entire node (or column of nodes). Thus, a multitude of pulses are all directed at the same area (i.e. 100% overlap). The width of the center region that is not irradiated by edge portions of any of the pulses thus is maximized to be the same width as the top hat portion of a single beam. In this region, the avoidance of beam edges will result in more uniformly crystallized regions. If a polygonal scanner is used “pulse-per-facet,” the reflectivity of the facets can further be optimized to achieve a certain desired pulse energy sequence, for example, a lower initial pulse energy density to create small-grain polycrystalline material with optimum properties for further cumulative ELA processing. Also, the last pulse or last few pulses may have lower energy density to induce surface melting for creating a smoother film surface with less pronounced protrusions at the grain boundaries.

Thus, when the short scan velocity has the same magnitude as the long scan velocity during anti-parallel scanning, the beam is stationary at the surface. Previously, it was recognized that with repetitive radiations with the same beam without shifting it, any non-uniformities in that beam may have amplified effects and may result in material non-uniformity. Here, it should be noted that while the beams overlap 100%, they actually travel over a different path (deflected from the optical axis) so that any optical distortions from imperfections of the optics are constantly changing. In other words, any beam non-uniformities resulting from optical distortions could be averaged by the beam using different parts of the optical elements. Additionally, it may actually be preferred to have a small non-zero scan velocity (i.e., resulting in less than 100% overlap, for example 98%, 95%, or 90%) to further average beam non-uniformities that result from systematic non-uniformities of the laser pulses.

In some embodiments, a short scan velocity also has a component that is perpendicular to the direction of the long scan velocity. This perpendicular component results in the beam being laterally displaced during the short scan. FIG. 9 depicts a superimposed scan of a thin film 400 using a diagonal short scan velocity 925 having a component perpendicular to the direction of the long scan velocity 910. The scan shown in FIG. 9 results in a diagonal effective scan of the film. The scan shown in FIG. 9 is substantially similar to the scan depicted in FIG. 3 except that the mirror and the optics are designed such that the beam 405 is deflected in a direction diagonal to the long scan velocity 910. Note that the parallel component of the short scan velocity still needs to be such that a certain desired overlap between the pulses is established, thus, the short scan velocity 925 is generally higher than the short scan velocity in those cases where there it has no perpendicular component (FIGS. 2, 3, 4, 8).

In FIG. 9a, beam 405 is directed to mirror 900 that is positioned at an angle 902 to the optical axis 901 and therefore deflects beam at an angle 904 from the optical axis. This results in the beam being directed to and irradiating location a of the film 400. FIG. 9b depicts a laser beam being directed to mirror 900 that is now positioned at angle 907 from the optical axis resulting in no deflection from the optical axis 901. Thus, the beam irradiates location b on the film 400. FIG. 9c depicts the beam 405 being directed to mirror 900 that is now positioned at an angle 912 from the optical axis 901 and therefore deflects beam at an angle 909 from the optical axis. This deflection results in the beam being redirected to and irradiate a location c of the film 400. FIG. 9d depicts regions a, b, and c are all overlapping, and staggered diagonally, with the required overlap, e.g., 4 μm in a line-scan 2-shot SLS process. This completes the crystallization of a first area for later TFT pixel or circuit manufacturing. In FIG. 9d, the film continues to move in the (−y) direction while the mirror has been moved back to its starting position in FIG. 9a. The movement toward the laser beam 405 causes the laser beam being directed to and irradiating location d on the thin film, which is the first pulse in a second area for TFT pixel or circuits and which does not overlap with the first area. The process continues as previously; in FIG. 9e, the mirror is rotated to the facet in 9b, resulting in the laser beam being directed to and irradiating location e on the film.

Lateral displacement of a line beam as disclosed in U.S. Publication Ser. No. 10/056,990, “Systems and Methods for the Crystallization of Thin Films,” which discloses a multi-scan diagonal process, can be effective in averaging out non-uniformities from optical distortion or stemming from the beam. If the effective scan velocity along the direction of the long scan during the anti-parallel scan is zero, then the beam motion may even be entirely in the direction perpendicular to the scanning direction.

While the present method is thus effective for doing SAC using certain line-beam crystallization techniques, it may not be as suitable for 2D projection SLS where non-periodic placement of pulses is best achieved in the time domain to have the benefits of less detrimental effects of stage wobble and beam distortion. Stage wobble, as used herein, refers to the erroneous movement of the stage between pulses, predominantly in a direction perpendicular to the scan direction. The effects of stage wobble can be reduced by reducing the time interval between overlapping pulses. For line-type crystallization schemes (i.e., having a beam that is uniform in the direction perpendicular to the scanning direction), the issue of stage wobble is significantly reduced as the perpendicular component thereof has no effect on the crystallization. In addition, line-scan SLS in particular typically uses lasers with significantly higher repetition rate (for example, three or six or more kHz or even up to 10 s of kHz), so that stage errors in between pulses are already minimized.

### EXAMPLES

For a 6 kHz line-scan SLS process needing 30 pulses to process an entire pixel TFT or circuit region, 200 scans per second are performed. If one scan is performed by a single facet, for example, using a polygonal mirror having eight facets, this requires a mirror rotation rate of 25 Hz=1500 rpm. If each radiation is done by a single facet, a 750 Hz=45,000 rpm scanner is required. For pulse-per-facet, a larger number of facets may be used, for example 20; this will then have to rotate at 300 Hz=18,000 rpm. Scanner motors are commercially available with speeds as low as 300 rpm but more commonly over lk and up to 10 s of thousand rpm, e.g., 55k rpm; for example, from Lincoln Laser Company.

For a 600 Hz ELA process needing 15 pulses to process an entire region, 40 scans per second are performed. Performing this using a polygonal mirror scan-per-facet may not be so attractive as rotation speeds become very low (for example, 5 Hz or 300 rpm for an eight facet mirror). For example, a galvanometer-based scanner can be used. In another embodiment, a polygonal scanner can be used pulse-per-facet. Also, translational scanners may be used.

While there have been shown and described examples of the present invention, it will be readily apparent to those skilled in the art that various changes and modifications may be made therein without departing from the scope of the invention.

What is claimed is:

1. A method for processing a thin film, the method comprising:
generating a plurality of laser beam pulses from a pulsed laser source, wherein each laser beam pulse has a fluence selected to melt the thin film and, upon cooling, induce crystallization in the thin film;
directing a first laser beam pulse onto a thin film using a first beam path;
advancing the thin film at a constant first scan velocity in a first direction; and
deflecting a second laser beam pulse from the first beam path to a second beam path using an optical scanning element such that the deflection results in the film experiencing a second scan velocity of the laser beam pulses relative to the thin film,
wherein the second scan velocity is less than the first scan velocity.

2. The method of claim 1, wherein each laser beam pulse has a fluence selected to completely melt the thin film.

3. The method of claim 1, wherein the crystallization comprises a sequential lateral solidification (SLS) process.

4. The method of claim 1, wherein each laser beam pulse has a fluence selected to partially melt the thin film.

5. The method of claim 1, wherein the crystallization comprises a line beam excimer laser annealing (ELA) process.

6. The method of claim 1, wherein the optical scanning element is selected from the group consisting of a tilting mirror, a rotating mirror, a linearly movable optical element and a polygonal scanner.

7. The method of claim 1, wherein the optical scanning element comprises a polygonal scanner and the second pulse is directed to a same facet as the first pulse.

8. The method of claim 1, wherein the optical scanning element comprises a polygonal scanner and the second pulse is directed to a different facet from the first pulse.

9. The method of claim 1, wherein the crystallization is complete in a single scan.

10. The method of claim 1, further comprising directing a third beam pulse onto the thin film using the first beam path.

11. A method for processing a thin film, the method comprising:
defining a plurality of regions comprising a first region and a second region;
generating a plurality of laser beam pulses from a pulsed laser source, wherein each laser beam pulse has a fluence selected to melt the thin film and, upon cooling, induce crystallization in the thin film;
advancing the thin film at a constant first scan velocity in a first direction resulting in a first scan direction; and
deflecting at least two of the laser beam pulses using an optical scanning element such that the beam pulses scan the first region in the film at a second scan velocity until the first region is entirely processed,
wherein the second scan velocity is less than the first scan velocity.

12. The method of claim 11, wherein each laser beam pulse has a fluence selected to completely melt the thin film.

13. The method of claim 11, wherein the crystallization comprises a sequential lateral solidification (SLS) process.

14. The method of claim 11, wherein each laser beam pulse has a fluence selected to partially melt the thin film.

15. The method of claim 11, wherein the crystallization comprises a line beam excimer laser annealing (ELA) process.

16. The method of claim 11, wherein the optical scanning element is selected from the group consisting of a tilting mirror, a rotating mirror, a linearly movable optical element and a polygonal scanner.

17. The method of claim 11, wherein the optical scanning element comprises a polygonal scanner and a second laser pulse is directed to a same facet as the first laser pulse.

18. The method of claim 11, wherein the optical scanning element comprises a polygonal scanner and a second laser pulse is directed to a different facet from the first laser pulse.

19. The method of claim 11, wherein the crystallization is complete in a single scan.

20. The method of claim 11, further comprising after the first region is scanned at the second scan velocity, irradiating the second region at the first scan velocity.

21. A thin film processed according to the method of claim 1.

22. A device comprising a thin film processed according to method of claim 1, wherein the device comprises a plurality of electronic circuits placed within the plurality of crystallized regions of the thin film.

23. The device of claim 22, wherein the device comprises a display device.

24. A system for crystallization of a thin film, the system comprising:
a pulsed laser source generating a plurality of laser beam pulses, wherein each laser beam pulse has a fluence selected to melt the thin film and, upon cooling, induce crystallization in the thin film;
optics for directing the laser beam onto the thin film using a first beam path;
a constant velocity scanning element for securing the thin film and advancing the thin film at a constant first scan velocity in a first direction resulting in a first scan direction; and
an optical scanning element for deflecting the laser beam from the first beam path to a second beam path such that the deflection results in the film experiencing a second scan velocity of the laser beam pulses relative to the thin film, wherein the second scan velocity is less than the first scan velocity.

25. The system of claim 24, wherein the optical scanning element is selected from the group consisting of a tilting mirror, a rotating mirror, a linearly movable optical element and a polygonal scanner.

26. The system of claim 24, wherein the optical scanning element comprises a polygonal scanner and a second laser pulse is directed to a same facet as a first laser pulse.

27. The system of claim 24, wherein the optical scanning element comprises a polygonal scanner and a second laser pulse is directed to a different facet from a first laser pulse.

28. The system of claim 24, wherein the crystallization is complete in a single scan.

29. A thin film processed according to the method of claim 11.

30. A device comprising a thin film processed according to method 11, wherein the device comprises a plurality of electronic circuits placed within the plurality of crystallized regions of the thin film.
